(19) United States
(12) Patent Application Publication
(10) Pub. No.: US 2003/0211245 A1
(43) Pub. Date: Nov. 13, 2003

(54) Fabrication of an article having a thermal barrier coating system, and the article

(76) Inventors: Irene Spitsberg, Loveland, OH (US); Robert William Bruce, Loveland, OH (US)

Correspondence Address: GENERAL ELECTRIC COMPANY, ANDREW C HESS, GE AIRCRAFT ENGINES, ONE NEUMANN WAY M/D H17, CINCINNATI, OH, 452156301

(21) Appl. No.: 09/943,782

(22) Filed: Aug. 31, 2001

(51) Int. Cl. C23C 14/30

(52) U.S. Cl. 427/255.36; 427/596; 427/255.32; 427/253; 427/372.2

(57) ABSTRACT

An article protected by a thermal barrier coating system is fabricated by providing an article substrate having a substrate surface; and thereafter producing a pre-oxidized bond coat on the substrate surface by depositing a bond coat on the substrate surface, the bond coat having a bond coat surface, and controllably oxidizing the bond coat surface to form a pre-oxidized bond coat surface. A thermal barrier coating is thereafter deposited overlying the pre-oxidized bond coat surface. The thermal barrier coating is yttria-stabilized zirconia having a yttria content of from about 3 percent by weight to about 5 percent by weight of the yttria-stabilized zirconia.

This invention relates to thermal barrier coating systems such as used to protect some components of gas turbine engines and, more particularly, to the treatment of the bond coat surface and the composition of the thermal barrier coating.

### BACKGROUND OF THE INVENTION

Higher operating temperatures for gas turbine engines are continuously sought in order to increase their efficiency. However, as operating temperatures increase, the high temperature durability of the components of the engine must correspondingly increase. Significant advances in high-temperature capabilities have been achieved through the formulation of nickel- and cobalt-base superalloys. Nonetheless, when used to form components of the turbine, combustor and augmentor sections of a gas turbine engine, such alloys alone are often susceptible to damage by oxidation and hot corrosion attack and may not retain adequate mechanical properties. For this reason, these components are often protected by an environmental and/or thermal-insulating coating, the latter of which is termed a thermal barrier coating (TBC) system. Ceramic materials and particularly yttria-stabilized zirconia (YSZ) are widely used as a thermal barrier coating (TBC), or topcoat, of TBC systems used on gas turbine engine components. The TBC employed in the highest-temperature regions of gas turbine engines is typically deposited by electron beam physical vapor deposition (EBPVD) techniques that yield a columnar grain structure that is able to expand and contract without causing damaging stresses that lead to spallation.

To be effective, TBC systems must have low thermal conductivity, strongly adhere to the article, and remain adherent throughout many heating and cooling cycles. The latter requirement is particularly demanding due to the different coefficients of thermal expansion between ceramic topcoat materials and the superalloy substrates they protect. To promote adhesion and extend the service life of a TBC system, an oxidation-resistant bond coat is usually employed. Bond coats are typically in the form of overlay coatings such as MCrAlX (where M is iron, cobalt, and/or nickel, and X is yttrium or another rare earth element), or diffusion aluminide coatings. A notable example of a diffusion aluminide bond coat contains platinum aluminide (NiPtAl) intermetallic. When a bond coat is applied, a zone of interdiffusion forms between the substrate and the bond coat. This zone is typically referred to as a diffusion zone. The diffusion zone beneath an overlay bond coat is typically much thinner than the diffusion zone beneath a diffusion bond coat.

During the deposition of the ceramic TBC and subsequent exposures to high temperatures, such as during engine service, bond coats of the type described above oxidize to form a tightly adherent alumina (aluminum oxide or Al₂O₃) layer or scale that protects the underlying structure from catastrophic oxidation and also adheres the TBC to the bond coat. The service life of a TBC system is typically limited by spallation at or near the interfaces of the alumina scale with the bond coat or with the TBC. The spallation is induced by thermal fatigue as the article substrate and the thermal barrier coating system are repeatedly heated and cooled during engine service.

There is a need for an understanding of the specific mechanisms that lead to the thermal fatigue failure of the protective system, and for structures that extend the life of the coating before the incidence of such failure. The present invention fulfills this need, and further provides related advantages.

### BRIEF SUMMARY OF THE INVENTION

The present invention provides an approach for fabricating an article protected by a thermal barrier coating system, and articles protected by the thermal barrier coating system. The life of the thermal barrier coating system is extended under conditions of thermal fatigue by delaying the onset of the alumina scale interface failure mode and also reducing the delamination of the thermal barrier coating.

A method of fabricating an article protected by a thermal barrier coating system comprises the steps of providing an article substrate having a substrate surface, and thereafter producing a pre-oxidized bond coat on the substrate surface. The step of producing the pre-oxidized bond coat includes the steps of depositing a bond coat on the substrate surface, the bond coat having a bond coat surface, and controllably oxidizing the bond coat surface to form a pre-oxidized bond coat surface. A thermal barrier coating is thereafter deposited overlying the pre-oxidized bond coat surface. The thermal barrier coating comprises yttria-stabilized zirconia having a yttria content of from about 3 percent by weight to about less than 6 percent by weight of the yttria-stabilized zirconia, preferably from about 3.8 to about 4.2 percent by weight of the yttria-stabilized zirconia. The thermal barrier coating is preferably deposited by a physical vapor deposition technique such as electron beam physical vapor deposition, although other techniques may be used.

The article substrate preferably is a nickel-base superalloy, and most preferably is a component of a gas turbine engine. The bond coat may be a diffusion aluminide bond coat such as a platinum aluminide bond coat, or it may be an overlay bond coat.

The step of controllably oxidizing the protective coating preferably includes the step of heating the protective coating in an atmosphere having a partial pressure of oxygen of from about 10⁻⁵ mbar to about 10³ mbar, more preferably from about 10⁻⁵ mbar to about 10⁻², at an oxidizing temperature of from about 1800° F. to about 2100° F., and for a time of from about ½ hour to about 3 hours. Most preferably, the controllable oxidation is performed by heating the protective coating to a pre-oxidation temperature of from about 2000° F. to about 2100° F. in a heating time of no more than about 45 minutes, preferably from about 1 to about 45 minutes, and more preferably from about 15 to about 35 minutes, and thereafter holding at the pre-oxidation temperature for a time of from about ½ hour to about 3 hours, in an atmosphere having a partial pressure of oxygen of about 10⁻⁴.

The present approach addresses two major mechanisms of thermal fatigue failure in thermal barrier coating systems. The controlled oxidation of the bond coat surface improves the bond strength between the bond coat and the alumina scale, and also reduces the growth rate of the alumina scale, so that the alumina scale reaches its critical thickness after longer times. As a result, failure of the thermal barrier coating system during thermal fatigue is delayed, improving its life. The selection of the yttria-stabilized zirconia with low yttrium content reduces the tendency of the thermal barrier coating to fail and to debond from the alumina as a result of differential thermal strains and stresses during thermal fatigue cycling, and also reduces the differential thermal strains and stresses on the alumina/bond coat interface. As a result, failure of the thermal barrier coating system during thermal fatigue is delayed, improving its life.

Other features and advantages of the present invention will be apparent from the following more detailed description of the preferred embodiment, taken in conjunction with the accompanying drawings, which illustrate, by way of example, the principles of the invention. The scope of the invention is not, however, limited to this preferred embodiment.

### BRIEF DESCRIPTION OF THE DRAWINGS

FIG. 1 is a perspective view of a turbine blade;

FIG. 2 is an enlarged schematic sectional view through the turbine blade of FIG. 1, taken on lines 2-2; and

FIG. 3 is a block flow diagram of an approach for preparing a coated gas turbine airfoil.

### DETAILED DESCRIPTION OF THE INVENTION

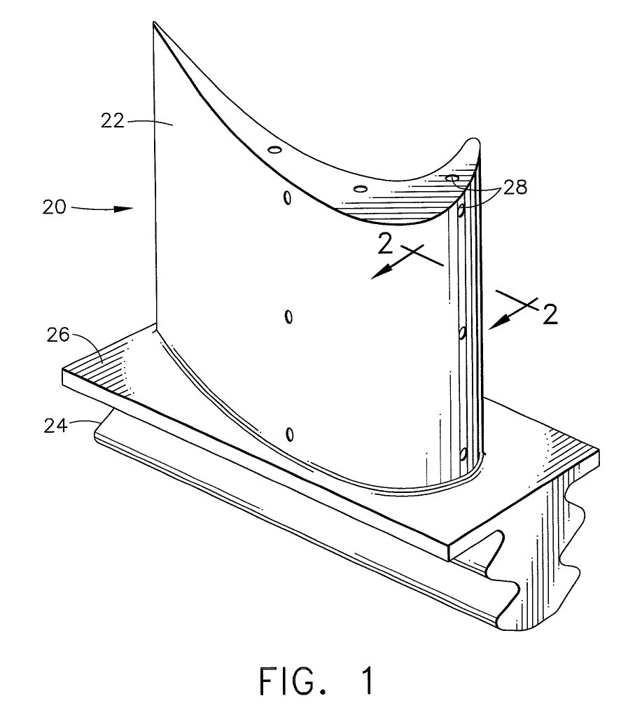

FIG. 1 depicts a component article of a gas turbine engine such as a turbine blade or turbine vane, and in this illustration a turbine blade 20. The turbine blade 20 is formed of any operable material, but is preferably a nickel-base superalloy. The turbine blade 20 includes an airfoil section 22 against which the flow of hot exhaust gas is directed. (The turbine vane or nozzle has a similar appearance in respect to the pertinent airfoil section, but typically includes other end structure to support the airfoil.) The turbine blade 20 is mounted to a turbine disk (not shown) by a dovetail 24 which extends downwardly from the airfoil 22 and engages a slot on the turbine disk. A platform 26 extends longitudinally outwardly from the area where the airfoil 22 is joined to the dovetail 24. A number of internal passages extend through the interior of the airfoil 22, ending in openings 28 in the surface of the airfoil 22. During service, a flow of cooling air is directed through the internal passages to reduce the temperature of the airfoil 22.

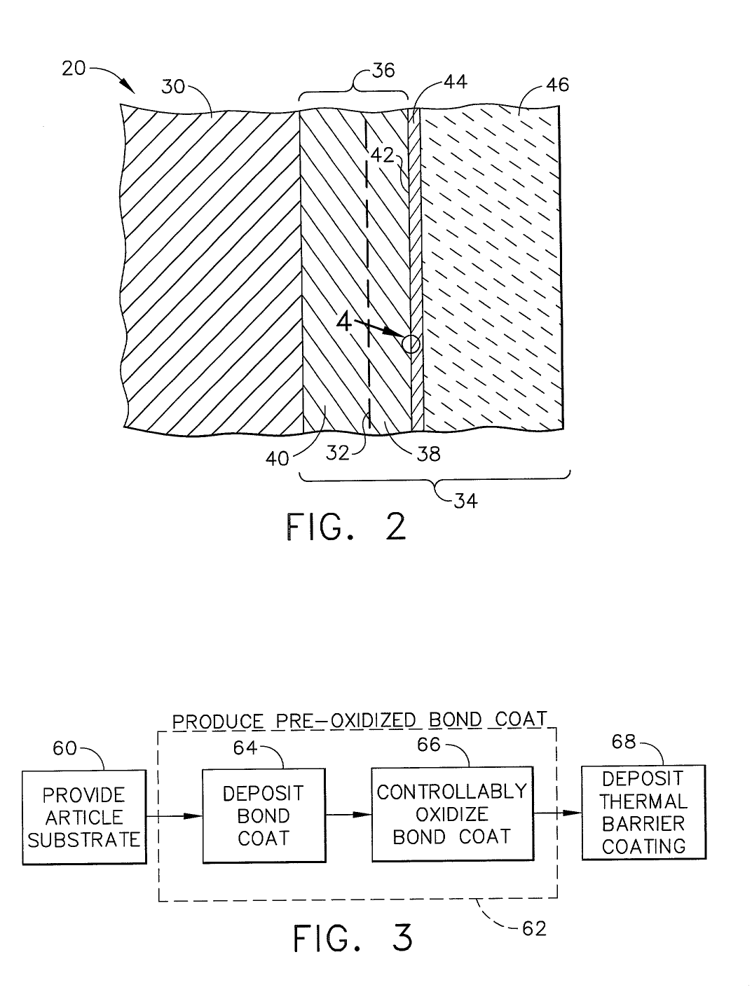

FIG. 2 is a schematic sectional view, not drawn to scale, through a portion of the turbine blade 20, here the airfoil section 22. The turbine blade 20 has a body that serves as a substrate 30 with a surface 32. Overlying and contacting the surface 32 of the substrate 30, and also extending downwardly into the substrate 30, is a thermal barrier coating system 34 including a protective coating, which in this case is termed a bond coat 36. The bond coat 36 includes a deposited layer 38 and a diffusion zone 40 that is the result of interdiffusion of material from the deposited layer 38 with material from the substrate 30. The process that deposits the deposited layer 38 onto the surface 32 of the substrate 30 is performed at elevated temperature, so that during deposition the material of the deposited layer 38 interdiffuses into and with the material of the substrate 30, forming the diffusion zone 40. The diffusion zone 40, indicated by a dashed line in FIG. 2, is a part of the bond coat 36 but extends downward into the substrate 30.

The bond coat 36 has an outwardly facing bond coat surface 42 remote from the surface 32 of the substrate 30. An alumina (aluminum oxide, or Al₂O₃) scale 44 forms at this bond coat surface 42 by oxidation of the aluminum in the bond coat 36 at the bond coat surface 40. A ceramic thermal barrier coating 46 overlies and contacts the bond coat surface 42 and the alumina scale 44 thereon.

FIG. 3 is a block flow diagram of a preferred approach for fabricating an article. An article and thence the substrate 30 are provided, numeral 60. The article is preferably a component of a gas turbine engine such as a gas turbine blade 20 or vane (or “nozzle”, as the vane is sometimes called), see FIG. 1. The article is typically a single crystal article, a preferentially oriented polycrystal, or a randomly oriented polycrystal. The article is most preferably made of a nickel-base superalloy. As used herein, “nickel-base” means that the composition has more nickel present than any other element. The nickel-base superalloys are typically of a composition that is strengthened by the precipitation of gamma-prime phase. The preferred nickel-base alloy has a composition, in weight percent, of from about 4 to about 20 percent cobalt, from about 1 to about 10 percent chromium, from about 5 to about 7 percent aluminum, from 0 to about 2 percent molybdenum, from about 3 to about 8 percent tungsten, from about 4 to about 12 percent tantalum, from 0 to about 2 percent titanium, from 0 to about 8 percent rhenium, from 0 to about 6 percent ruthenium, from 0 to about 1 percent niobium, from 0 to about 0.1 percent carbon, from 0 to about 0.01 percent boron, from 0 to about 0.1 percent yttrium, from 0 to about 1.5 percent hafnium, balance nickel and incidental impurities.

A most preferred alloy composition is Rene' N5, which has a nominal composition in weight percent of about 7.5 percent cobalt, about 7 percent chromium, about 6.2 percent aluminum, about 6.5 percent tantalum, about 5 percent tungsten, about 1.5 percent molybdenum, about 3 percent rhenium, about 0.05 percent carbon, about 0.004 percent boron, about 0.15 percent hafnium, up to about 0.01 percent yttrium, balance nickel and incidental impurities. Other operable superalloys include, for example, Rene' N6, which has a nominal composition in weight percent of about 12.5 percent cobalt, about 4.2 percent chromium, about 1.4 percent molybdenum, about 5.75 percent tungsten, about 5.4 percent rhenium, about 7.2 percent tantalum, about 5.75 percent aluminum, about 0.15 percent hafnium, about 0.05 percent carbon, about 0.004 percent boron, about 0.01 percent yttrium, balance nickel and incidental impurities; Rene 142, which has a nominal composition, in weight percent, of about 12 percent cobalt, about 6.8 percent chromium, about 1.5 percent molybdenum, about 4.9 percent tungsten, about 6.4 percent tantalum, about 6.2 percent aluminum, about 2.8 percent rhenium, about 1.5 percent hafnium, about 0.1 percent carbon, about 0.015 percent boron, balance nickel and incidental impurities; CMSX-4, which has a nominal composition in weight percent of about 9.60 percent cobalt, about 6.6 percent chromium, about 0.60 percent molybdenum, about 6.4 percent tungsten, about 3.0 percent rhenium, about 6.5 percent tantalum, about 5.6 percent aluminum, about 1.0 percent titanium, about 0.10 percent hafnium, balance nickel and incidental impurities; CMSX-10, which has a nominal composition in weight percent of about 7.00 percent cobalt, about 2.65 percent chromium, about 0.60 percent molybdenum, about 6.40 percent tungsten, about 5.50 percent rhenium, about 7.5 percent tantalum, about 5.80 percent aluminum, about 0.80 percent titanium, about 0.06 percent hafnium, about 0.4 percent niobium, balance nickel and incidental impurities; PWA1480, which has a nominal composition in weight percent of about 5.00 percent cobalt, about 10.0 percent chromium, about 4.00 percent tungsten, about 12.0 percent tantalum, about 5.00 percent aluminum, about 1.5 percent titanium, balance nickel and incidental impurities; PWA1484, which has a nominal composition in weight percent of about 10.00 percent cobalt, about 5.00 percent chromium, about 2.00 percent molybdenum, about 6.00 percent tungsten, about 3.00 percent rhenium, about 8.70 percent tantalum, about 5.60 percent aluminum, about 0.10 percent hafnium, balance nickel and incidental impurities; and MX-4, which has a nominal composition as set forth in U.S. Pat. No. 5,482,789, in weight percent, of from about 0.4 to about 6.5 percent ruthenium, from about 4.5 to about 5.75 percent rhenium, from about 5.8 to about 10.7 percent tantalum, from about 4.25 to about 17.0 percent cobalt, from 0 to about 0.05 percent hafnium, from 0 to about 0.06 percent carbon, from 0 to about 0.01 percent boron, from 0 to about 0.02 percent yttrium, from about 0.9 to about 2.0 percent molybdenum, from about 1.25 to about 6.0 percent chromium, from 0 to about 1.0 percent niobium, from about 5.0 to about 6.6 percent aluminum, from 0 to about 1.0 percent titanium, from about 3.0 to about 7.5 percent tungsten, and wherein the sum of molybdenum plus chromium plus niobium is from about 2.15 to about 9.0 percent, and wherein the sum of aluminum plus titanium plus tungsten is from about 8.0 to about 15.1 percent, balance nickel and incidental impurities. The use of the present invention is not limited to these preferred alloys, and has broader applicability.

A controllably pre-oxidized bond coat 36 is produced on the surface 32 of the substrate 30, numeral 62. As part of this step 62, the bond coat 36 is deposited, numeral 64. The bond coat is preferably a diffusion aluminide bond coat, produced by depositing an aluminum-containing layer onto the substrate 30 and interdiffusing the aluminum-containing layer with the substrate 30 to produce the deposited layer 38 and the diffusion zone 40 shown in FIG. 2. The bond coat may be a simple diffusion aluminide, or it may be a more-complex diffusion aluminide wherein another layer, preferably platinum, is first deposited upon the surface 32, and the aluminum-containing layer is deposited over the first-deposited layer. In either case, the aluminum-containing layer may be doped with other elements that modify the bond coat. The basic application procedures for these various types of bond coats are known in the art, except for the modifications to the processing and structure discussed herein.

Because the platinum-aluminide diffusion aluminide is preferred, its deposition will be described in more detail. A platinum-containing layer is first deposited onto the surface 32 of the substrate 30. The platinum-containing layer is preferably deposited by electrodeposition. For the preferred platinum deposition, the deposition is accomplished by placing a platinum-containing solution into a deposition tank and depositing platinum from the solution onto the surface 32 of the substrate 30. An operable platinum-containing aqueous solution is Pt(NH₃)₄HPO₄ having a concentration of about 4-20 grams per liter of platinum, and the voltage/current source is operated at about ½-10 amperes per square foot of facing article surface. The platinum first coating layer, which is preferably from about 1 to about 6 micrometers thick and most preferably about 5 micrometers thick, is deposited in 1-4 hours at a temperature of 190-200° F.

A layer comprising aluminum and any modifying elements is deposited over the platinum-containing layer by any operable approach, with chemical vapor deposition preferred. In that approach, a hydrogen halide activator gas, such as hydrogen chloride, is contacted with aluminum metal or an aluminum alloy to form the corresponding aluminum halide gas. Halides of any modifying elements are formed by the same technique. The aluminum halide (or mixture of aluminum halide and halide of the modifying element, if any) contacts the platinum-containing layer that overlies the substrate 30, depositing the aluminum thereon. The deposition occurs at elevated temperature such as from about 1825° F. to about 1975° F. so that the deposited aluminum atoms interdiffuse into the substrate 30 during a 4 to 20 hour cycle.

The bond coat 36 is controllably oxidized to form the preoxidized bond coat surface 42, numeral 66. Step 66 typically follows step 64, but they may be performed at least in part concurrently. The parameters of the oxidation processing are controlled to produce the desired thin, pure alumina scale 44. The controlled parameters include the partial pressure of oxygen, the temperature range of the pre-oxidation treatment 66, the heating rate to the pre-oxidation temperature, and the time of the pre-oxidation treatment.

To form the desired alumina scale 44, the partial pressure of oxygen is preferably between about 10⁻⁵ mbar (millibar) and about 10³ mbar, more preferably between about 10⁻⁵ mbar and about 10⁻² mbar,. Most preferably, the partial pressure of about 10⁴ mbar, which produces the best thermal fatigue life in furnace cycle testing. The pre-oxidation step 66 is performed without combustion gas or other sources of corrodants present, which otherwise interfere with the formation of the desired high-purity alumina scale 44. The pre-oxidation temperature is preferably from about 1800° F. to about 2100° F., most preferably from about 2000° F. to about 2100° F. The higher pre-oxidation temperatures are preferred to favor the formation of alpha alumina, but the indicated maximum temperature may not be exceeded due to the potential for damage of the superalloy substrate. The article to be pre-oxidized is desirably heated from room temperature to the pre-oxidation temperature in about 45 minutes or less, more preferably from about 15 to about 35 minutes. If the heating is too slow, there is an opportunity for the formation of detrimental, less adherent, oxide phases within the alumina scale 44. The adherence of the alumina scale 44 to the protective coating is therefore reduced. The time at the pre-oxidizing temperature is preferably from about ½ hour to about 3 hours, to achieve a pure alumina scale 44 having a thickness of from about 0.1 micrometer to about 1 micrometer.

If the pre-oxidation parameters lie outside these ranges, an alumina scale will be produced, but it will be less desirable than the alumina scale 44 produced by pre-oxidation within these ranges. Comparative microanalysis (scanning electron nucroscope and XPS) of alumina scale produced using the indicated pre-oxidation parameters and alumina scale produced outside the indicated pre-oxidation parameters disclosed variations in the nature of the alumina scale. Non-uniform microstructures resulted when the pre-oxidation pressure was greater than about 10⁻⁴ mbar. The non-uniformity increased when other elements than aluminum and oxygen were present in the alumina scale. Oxygen pressures within the range of from about 10⁻⁵ mbar to about 10³ mbar yielded desirable “ridge” type microstructures characteristic of alpha alumina when no elements other than aluminum and oxygen were present in the oxide. Low partial pressures of oxygen, below about 10⁻⁵ mbar, result in internal oxidation along with an outward diffusion of aluminum. Such a structure has a reduced adhesion to the protective coating 36.

The thermal barrier coating 46 is deposited overlying the pre-oxidized bond coat surface 42 and the alumina scale 44 that has formed thereon, numeral 68. The ceramic thermal barrier coating 46 is preferably from about 0.003 to about 0.010 inch thick, most preferably about 0.005 inch thick. The ceramic thermal barrier coating 46 may be deposited by any operable technique, such as electron beam physical vapor deposition or plasma spray.

The ceramic thermal barrier coating 46 is yttria-stabilized zirconia (YSZ), which is zirconium oxide containing yttrium oxide that stabilizes the phase structure of the zirconium oxide. In the past, it has been known to use YSZ with from about 2 to about 12 weight percent of yttrium oxide. The prevailing industrial practice is to use YSZ with about 7 weight percent yttrium oxide (termed 7YSZ herein).

The present invention requires the use of YSZ having a yttria content of from about 3 percent by weight to about less than 6 percent by weight of the yttria-stabilized zirconia. More preferably, the YSZ has a yttria content of from about 3.8 percent by weight to about 4.2 percent by weight of the yttria-stabilized zirconia, or about 4 weight percent yttria (termed 4YSZ herein). The effective density of 4YSZ is about 10 percent less than that of 7YSZ, due to a lower fraction of sintered columnar grain boundaries in the 4YSZ. The 4YSZ is a more open, more loosely bound array of columnar grains than is the 7YSZ. This altered microstructure does not adversely affect the thermal insulating properties of the YSZ, because the columnar grains of the YSZ extend generally perpendicular to the bond coat surface 42. The lower fraction of sintered grain boundaries increases the in-plane mechanical compliance of the 4YSZ as compared with the 7YSZ, so that during thermal fatigue cycling there is less stress placed on the alumina scale 44 and its interfaces with the bond coat 36 and the thermal barrier coating 46. If the YSZ of the present invention has less than about 3 percent by weight of yttria, there is insufficient yttria to stabilize the zirconia, and the formation of an excessive amount of monoclinic zirconia leads to premature failure of the thermal barrier coating. If the YSZ of the present invention has more than about 6 percent by weight of yttria, the density of the YSZ becomes too high to realize the advantages otherwise achieved.

To verify the effect of the altered chemistry of the YSZ, comparative studies were performed in which otherwise-identical specimens having 7YSZ and 4YSZ thermal barrier coatings 46 were furnace cycle tested (FCT) to 2075° F. with 1 hour cycle times. The number of cycles until failure was recorded. In a first series, with the YSZ in each case deposited at a lower temperature, the 7YSZ exhibited FCT lives of 505+/−23 cycles. Separate batches of the 4 YSZ exhibited FCT lives of 560+/23 cycles, 615+/−89 cycles, and 570+/−90 cycles. The 4YSZ had about a 15 percent life increase over the 7YSZ. In a second series, with the YSZ in each case deposited at a higher temperature, the 7YSZ exhibited FCT lives of 450+/−38 cycles and 400 +/−54 cycles. The 4YSZ exhibited an FCT life of 530+/−35 cycles. The FCT lives were generally lower as a result of the sintering of the YSZ boundaries in the higher temperature deposition process, but the 4YSZ had about a 30 percent life increase over the 7YSZ.

The pre-oxidizing of the bond coat surface 42 and the use of the YSZ with from about 3 percent by weight to about 5 percent by weight of yttria must be employed together in the present invention. The controlled oxidation of the protective coating surface improves the bond strength between the protective coating and the alumina scale, and also slows the growth of the alumina scale. By forming the alumina scale by a controlled oxidation, the slow-growing alumina scale 44 is formed, which reduces stresses posed at the alumina scale 44/protective coating 36 interface . This, in turn, delays the start of the delamination failures. The selection of the yttria-stabilized zirconia with low yttrium content reduces the tendency of the thermal barrier coating to fail and to debond from the alumina as a result of differential thermal strains and stresses during thermal fatigue cycling, and also reduces the differential thermal strains and stresses on the alumina/bond coat interface. Thus, both mechanisms of failure are addressed and their tendency to cause early failure is suppressed. Suppressing only one of the failure mechanisms may have some beneficial effect, but not as much beneficial effect as when the two failure mechanisms are treated together as here. As a result, failure of the thermal barrier coating system during thermal fatigue is delayed, improving its life.

Although a particular embodiment of the invention has been described in detail for purposes of illustration, various modifications and enhancements may be made without departing from the spirit and scope of the invention. Accordingly, the invention is not to be limited except as by the appended claims.

What is claimed is:

1. A method of fabricating an article protected by a thermal barrier coating system, comprising the steps of
providing an article substrate having a substrate surface; thereafter
producing a pre-oxidized bond coat on the substrate surface, the step of producing the pre-oxidized bond coat including the steps of
depositing a bond coat on the substrate surface, the bond coat having a bond coat surface, and
controllably oxidizing the bond coat surface to form a pre-oxidized bond coat surface; and thereafter
depositing a thermal barrier coating overlying the pre-oxidized bond coat surface, the thermal barrier coating comprising yttria-stabilized zirconia having a yttria content of from about 3 percent by weight to about less than 6 percent by weight of the yttria-stabilized zirconia.

2. The method of claim 1, wherein the step of providing the article substrate includes the step of
providing the article substrate comprising a nickel-base superalloy.

3. The method of claim 1, wherein the step of providing the article substrate includes the step of
providing the article substrate comprising a component of a gas turbine engine.

4. The method of claim 1, wherein the step of depositing the bond coat includes the step of
depositing a diffusion aluminide bond coat.

5. The method of claim 1, wherein the step of depositing the bond coat includes the step of
depositing a platinum aluminide bond coat.

6. The method of claim 1, wherein the step of controllably oxidizing the bond coat includes the step of
heating the bond coat in an atmosphere having a partial pressure of oxygen of from about 10⁻⁵ mbar to about 10³ mbar.

7. The method of claim 1, wherein the step of controllably oxidizing the bond coat includes the step of
heating the bond coat in an atmosphere having a partial pressure of oxygen of from about 10⁻⁵ mbar to about 10⁻² mbar.

8. The method of claim 1, wherein the step of controllably oxidizing the bond coat includes the step of
heating the bond coat in an atmosphere having a partial pressure of oxygen of about 10⁻⁴ mbar.

9. The method of claim 1, wherein the step of controllably oxidizing the bond coat includes the step of
heating the bond coat to an oxidizing temperature of from about 1800° F. to about 2100° F.

10. The method of claim 1, wherein the step of controllably oxidizing the bond coat includes the step of
heating the bond coat to an oxidizing temperature for a time of from about ½ hour to about 3 hours.

11. The method of claim 1, wherein the step of controllably oxidizing the bond coat includes the step of
heating the bond coat to a temperature of from about 2000° F. to about 2100° F., for a time of from about ½ hour to about 3 hours, and in an atmosphere having a partial pressure of oxygen of about 10⁻⁴ mbar.

12. The method of claim 1, wherein the steps of depositing the bond coat and controllably oxidizing the bond coat are performed concurrently.

13. The method of claim 1, wherein the step of controllably oxidizing the bond coat is performed after the step of depositing the bond coat.

14. The method of claim 1, wherein the step of depositing the thermal barrier coating includes the step of
depositing the thermal barrier coating by physical vapor deposition.

15. The method of claim 1, wherein the step of depositing the thermal barrier coating includes the step of
depositing the thermal barrier coating to have the yttria content from about 3.8 to about 4.2 percent by weight of the yttria-stabilized zirconia.

16. A method of fabricating an article protected by a thermal barrier coating system, comprising the steps of
providing an nickel-base superalloy article substrate comprising a component of a gas turbine engine and having a substrate surface; thereafter
depositing a platinum aluminide bond coat on the substrate surface, the bond coat having a bond coat surface; thereafter
controllably oxidizing the bond coat surface to form a pre-oxidized bond coat surface; and thereafter
depositing a thermal barrier coating overlying the pre-oxidized bond coat surface, the thermal barrier coating comprising yttria-stabilized zirconia having a yttria content of from about 3 percent by weight to about less than 6 percent by weight of the yttria-stabilized zirconia.

17. The method of claim 16, wherein the step of controllably oxidizing the bond coat includes the step of
heating the bond coat in an atmosphere having a partial pressure of oxygen of from about 10⁻⁵ mbar to about 10³ mbar.

18. The method of claim 16, wherein the step of controllably oxidizing the bond coat includes the step of
heating the bond coat to an oxidizing temperature of from about 1800° F. to about 2100° F.

19. The method of claim 16, wherein the step of depositing the thermal barrier coating includes the step of
depositing the thermal barrier coating to have the yttria content from about 3.8 to about 4.2 percent by weight of the yttria-stabilized zirconia.
